(19) United States
(12) Patent Application Publication
(10) Pub. No.: US 2024/0349496 A1
(43) Pub. Date: Oct. 17, 2024

(54) THREE-DIMENSIONAL MULTILAYER MEMORY WITH INTERCONNECTION OF LOW-RESISTANCE SILICIDES AND MANUFACTURING METHOD THEREOF

(71) Applicant: CHENGDU PBM TECHNOLOGY LTD., CHENGDU, Sichuan (CN)

(72) Inventors: KE WANG, Chengdu, Sichuan (CN); JACK ZEZHONG PENG, Chengdu, Sichuan (CN)

(21) Appl. No.: 18/044,141

(22) PCT Filed: Mar. 22, 2022
(86) PCT No.: PCT/CN2022/082219

§ 371 Date: Mar. 6, 2023

(30) Foreign Application Priority Data
Dec. 1, 2021 (CN) 202111451938.1

(51) Int. Cl. H10B 20/25

(52) U.S. Cl. CPC H10B 20/25

(57) ABSTRACT

A three-dimensional multilayer memory with interconnection of low-resistance silicides and a manufacturing method thereof are provided. The three-dimensional multilayer memory comprises an underlying circuit part and a base structure disposed on the underlying circuit part. The base structure is divided into two interdigitated structures which are independent of each other by a curved division trench, and comprises first conductive medium layers and insulating medium layers which are alternately stacked on each other. At least three memory cell holes are disposed side by side in the curved division trench, wherein a vertical electrode is disposed in each memory cell hole, and an insulating isolation pillar is disposed between two adjacent memory cell holes. The first conductive medium layers each comprise a low-resistance semiconductor layer and a low-resistance silicide layer, one stacking on top of the other. An insulating region is disposed in the low-resistance silicide layer, close to a storage medium.

### CROSS-REFERENCE TO RELATED APPLICATION

This patent application claims the benefit and priority of Chinese Patent Application No. 202111451938.1 filed with the China National Intellectual Property Administration on Dec. 1, 2021, the disclosure of which is incorporated by reference herein in its entirety as part of the present application.

### TECHNICAL FIELD

The present disclosure relates to semiconductor memory technologies.

### BACKGROUND

In the prior art, three-dimensional memory employs low-resistance semiconductors as interconnection lines in each stacking layer, the disadvantage of which is that the resistivity of the semiconductor is relatively high, especially when the length of a horizontal wire is usually hundreds, thousands of microns and above, so that the interconnection line formed by the low-resistance semiconductor has a great influence on reading and writing of the memory.

The application of a metal silicide may improve the circuit interconnection by reducing resistance of the interconnection line and contact resistance. However, in the previously disclosed 3D multilayer stacking memory devices, it is impossible to apply low-resistance silicide onto the low-resistance semiconductor layer of the horizontal wire. The reason is that such an arrangement may lead to a redundant connection between the low-resistance silicide and the storage medium, causing the storage medium in contact with the silicide also be programmed. Taking the anti-fuse storage medium as an example, the result is that, after the breakdown of the storage medium, a functional PN junction diode that should have been formed by a horizontal P-type (or N-type) semiconductor layer and a vertical N-type (or P-type) semiconductor is short-circuited by the redundant connection formed by the silicide on top of the horizontal P-type (or N-type) semiconductor layer and the vertical N-type (or P-type) semiconductor, and thus the reading/writing performance characteristics of the memory cell device are changed.

### SUMMARY

The technical problem to be solved by the present disclosure is to provide a three-dimensional multilayer memory with low-resistance silicide as an interconnection line, which has the characteristic of low-series resistance.

The present disclosure further provides a manufacturing method for a three-dimensional multilayer memory with interconnection of low-resistance silicides, which has the advantages of process simplified and high yield, in addition to the above-mentioned advantages of the manufactured memory.

The technical solution adopted by the present disclosure for solving the technical problem is as follows:

The three-dimensional multilayer memory with interconnection of low-resistance silicides comprises an underlying circuit part and a base structure disposed on top of the underlying circuit part. The base structure is divided into two interdigitated structures which are independent of each other by a curved division trench, referred to as a first interdigitated structure and a second interdigitated structure, respectively. The base structure comprises first conductive medium layers and insulating medium layers which are alternately stacked on each other from bottom to top. At least three memory cell holes are disposed side by side in the curved division trench, wherein a vertical electrode is disposed in each memory cell hole, and an insulating isolation pillar is disposed between two adjacent memory cell holes.

The first conductive medium layer comprises a low-resistance semiconductor. The vertical electrode and the low-resistance semiconductor in the interdigitated structure, as well as a storage medium therebetween form a memory structure.

The memory is a PN junction type semiconductor memory, a Schottky semiconductor memory, a resistance change memory; a magnetic phase change memory, a phase change memory or a ferroelectric memory.

The storage medium is an insulating medium.

The first conductive medium layer comprises a low-resistance semiconductor layer and a low-resistance silicide layer, one stacking on top of another.

An insulating region is disposed in the low-resistance silicide layer, close to a storage medium, and the insulating region is configured to isolate the low-resistance silicide in the low-resistance silicide layer from the storage medium.

Further, a buffer layer is disposed between the vertical electrode and the storage medium. The low-resistance silicide is a metal silicide; and the low-resistance semiconductor layer is heavily-doped polycrystalline silicon.

A manufacturing method for a three-dimensional multilayer memory with interconnection of low-resistance silicides comprises the following steps:
1) forming a base structure: a preset number of first conductive medium layers and a preset number of insulating medium layers are disposed in such a manner that the first conductive medium layers and the insulating medium layers are alternately stacked on each other to form the base structure:
2) trenching the base structure: a curved division trench is formed by trenching the base structure from a top layer to a bottom layer, thus the base structure is divided into two staggered and mutually separated interdigitated structures by the division trench; and
3) forming a preset number of memory cell holes in the division trench, where an insulating medium is disposed between the adjacent memory cell holes, a vertical electrode is disposed in each memory cell hole, and a storage medium layer is disposed between the vertical electrode and the interdigitated structure: the vertical electrode, the storage medium and the first conductive medium are all made of materials meeting the requirement of the preset memory, and the memory is a PN junction type semiconductor memory, a Schottky semiconductor memory, a resistance change memory, a magnetic phase change memory, a phase change memory, or a ferroelectric memory.

In step 1), the first conductive medium layers each comprises a low-resistance semiconductor layer and a low-resistance silicide layer with one stacking on top of another.

After step 2) and before step 3), the method further comprises the following steps:
A) etching a metal silicide layer on the inner wall of the division trench to form a recess; and
B) filling the recess formed in step A) with an insulating material.

In step 3), the memory cell hole is a through hole penetrating through the base structure.

Further, step B) comprises the following step: filling the division trench formed in step 2) and the recess formed in step A) with the insulating material.

Step 3) comprises the following steps:
3.1. vertically etching the filled insulating medium until the inner wall of the division trench is exposed, thus forming the memory cell holes disposed side by side along the division trench, wherein an insulating material is provided between the adjacent memory cell holes:
3.2. depositing the insulating material on the inner wall of each memory cell hole as the storage medium;
3.3. depositing a buffer material on the inner wall of each memory cell hole;
3.4. removing the insulating material and the buffer material at the bottom region of each memory cell hole to expose the underlying circuit; and
3.5. filling each memory cell hole with a vertical electrode material.

Alternatively, step B) comprises the following step: isotropically depositing the insulating material on the inner wall of the division trench to fill the recess formed in step A).

Step 3) comprises the following steps:
3.1. removing the insulating material covered on the inner wall of the division trench, and retaining the insulating material filled in the recess;
3.2. depositing the insulating material on the inner wall of the division trench as the storage medium;
3.3. depositing a buffer material on the inner wall of the division trench;
3.4. removing the insulating material and the buffer material at the bottom region at the position of a circuit connection in the division trench so as to expose the underlying circuit;
3.5. filling the division trench with a vertical electrode material;
3.6. vertically etching the vertical electrode material and the buffer material filled in the division trench so as to form various independent vertical electrodes separated by isolation holes; and
3.7. filling the isolation holes with the insulating material.

The present disclosure has the beneficial effects that the memory provided by the present disclosure has high memory density, and both lower interconnection resistance and contact resistance in the stacking layers, which is more beneficial for the more stable operation of the memory. The manufacturing method provided by the present disclosure is low in process cost and high in yield.

### BRIEF DESCRIPTION OF THE DRAWINGS

FIG. 1 is a three-dimensional diagram of a base structure.

FIG. 2 is a top view of a prototype structure in accordance with the present disclosure.

FIG. 3 is a sectional view of a prototype structure in accordance with the present disclosure from the front.

FIG. 4 is a schematic diagram of a prototype structure with a curved division trench in a top direction.

FIG. 5 is a sectional view of a prototype structure with a curved division trench in an A-A′ direction.

FIG. 6 is a schematic diagram of step A3 of embodiment 1 in a top direction of the prototype structure.

FIG. 7 is a sectional view of step A3 of embodiment 1 in an A-A′ direction of the prototype structure.

FIG. 8 is a schematic diagram of step A4 of embodiment 1 in a top direction of the prototype structure.

FIG. 9 is a sectional view of step A4 of embodiment 1 in an A-A′ direction of the prototype structure.

FIG. 10 is a schematic diagram of step A5 of embodiment 1 in a top direction of the prototype structure.

FIG. 11 is a sectional view of step A5 of embodiment 1 in an A-A′ direction of the prototype structure.

FIG. 12 is a schematic diagram of step A6 of embodiment 1 in a top direction of the prototype structure.

FIG. 13 is a sectional view of step A6 of embodiment 1 in an A-A′ direction of the prototype structure.

FIG. 14 is a schematic diagram of step A7 of embodiment 1 in a top direction of the prototype structure.

FIG. 15 is a sectional view of step A7 of embodiment 1 in an A-A′ direction of the prototype structure.

FIG. 16 is a schematic diagram of step A8 of embodiment 1 in a top direction of the prototype structure.

FIG. 17 is a sectional view of step A8 of embodiment 1 in an A-A′ direction of the prototype structure.

FIG. 18 is a sectional view of step B5 of embodiment 2 in an A-A′ direction of the prototype structure.

FIG. 19 is a sectional view of step C3 of embodiment 3 in an A-A′ direction of the prototype structure.

FIG. 20 is a schematic diagram of step C4 of embodiment 3 in a top direction of the prototype structure.

FIG. 21 is a sectional view of step C4 of embodiment 3 in an A-A′ direction of the prototype structure.

FIG. 22 is a schematic diagram of step C5 of embodiment 3 in a top direction of the prototype structure.

FIG. 23 is a sectional view of step C5 of embodiment 3 in an A-A′ direction of the prototype structure.

FIG. 24 is a sectional view of step C6 of embodiment 3 in an A-A′ direction of the prototype structure.

FIG. 25 is a sectional view of step C7 of embodiment 3 in an A-A′ direction of the prototype structure.

FIG. 26 is a schematic diagram of step C7 of embodiment 3 in a top direction of the prototype structure.

FIG. 27 is a schematic diagram of step D6 of embodiment 4 in a top direction of the prototype structure.

FIG. 28 is a sectional view of step D6 of embodiment 4 in an A-A′ direction of the prototype structure.

FIG. 29 is a schematic diagram of step D7 of embodiment 4 in a top direction of the prototype structure.

FIG. 30 is a schematic diagram of step D8 of embodiment 4 in a top direction of the prototype structure.

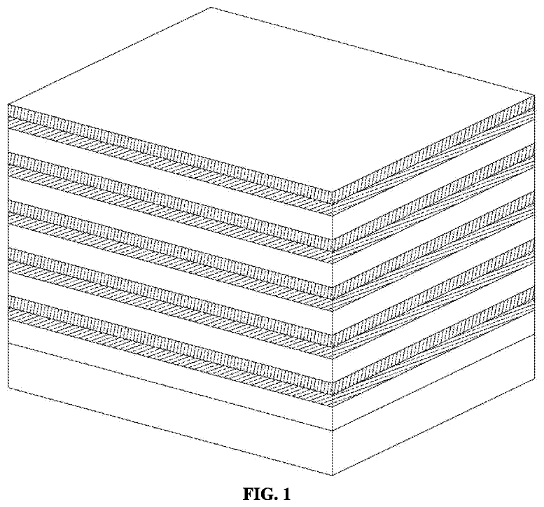

### DETAILED DESCRIPTION OF THE EMBODIMENTS

In an ideal state, the widths of the top and the bottom of a trench or hole formed by an etching process are consistent. However, in the actual process, the top and the bottom are difficult to be consistent. The sectional view of the prototype structure in an A-A′ direction is shown according to the actual situation, where the division trench is trapezoid with a wide upper part and a narrow lower part. For the sake of simplicity, the top view does not show such a trapezoidal structure and is hereby illustrated.

The various materials involved in the present disclosure may be made of one of the following four items:

| | | | | Low-resistance |
|---|---|---|---|---|
| | | | | semiconductor |
| | | | | layer (in first |
| | Vertical | | Storage | conductive |
| | electrode | Buffer layer | medium | medium layer) |
| 1 | N + | Low doped N-type | Insulating | P + |
| | Semiconductor | semiconductor | medium | Semiconductor |
| 2 | N + | Low doped N-type | Insulating | P-type |
| | Semiconductor | semiconductor | medium | Schottky metal, |
| | | | | such as Al, Ag, |
| | | | | Au, and Pt |
| 3 | P + | Low doped P-type | Insulating | N + |
| | Semiconductor | semiconductor | medium | Semiconductor |
| | | | | or |
| | | | | semiconductor |
| 4 | P + | Low doped P-type | Insulating | N + Poly, N + Si, |
| | Semiconductor | semiconductor | medium | IZO (Indium |
| | | | | Zinc Oxide) |
| | | | | and other N- |
| | | | | type Schottky |
| | | | | metal |

### Embodiment 1 (No Buffer Layer)

This embodiment is the first embodiment of a manufacturing method, comprising the following steps:

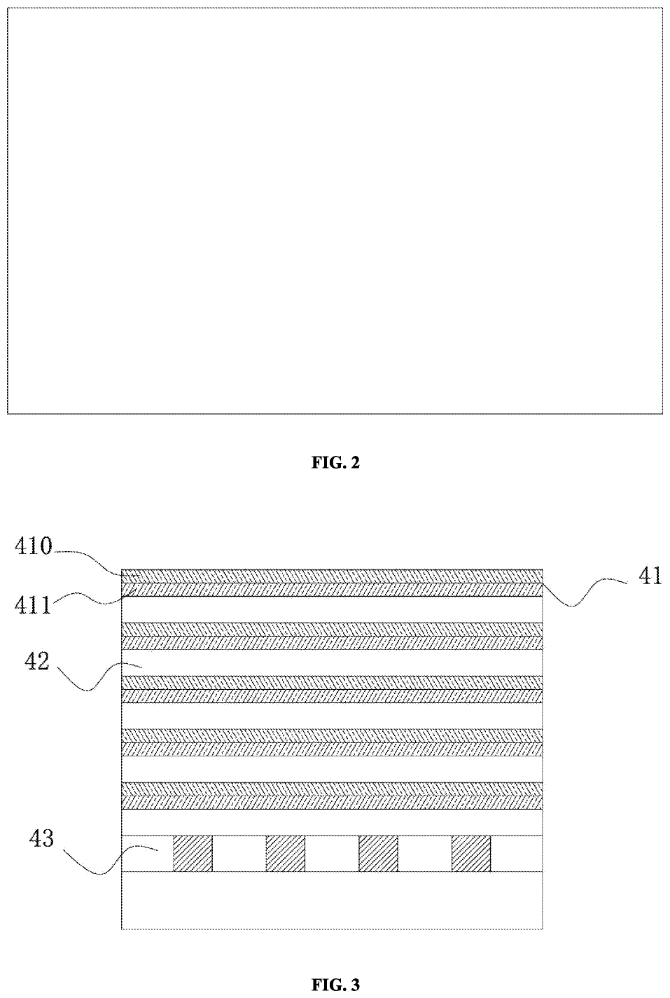

A1. A base structure is formed on an underlying circuit 43: a preset number of first conductive medium layers and a preset number of insulating medium layers are disposed in a manner that the first conductive medium layers 41 and the insulating medium layers 42 are alternately stacked on each other so as to form the base structure. The first conductive medium layers 41 each comprise a low-resistance silicide layer 410 and a low-resistance semiconductor layer 411, one stacking on top of another, referring to FIG. 2 and FIG. 3.

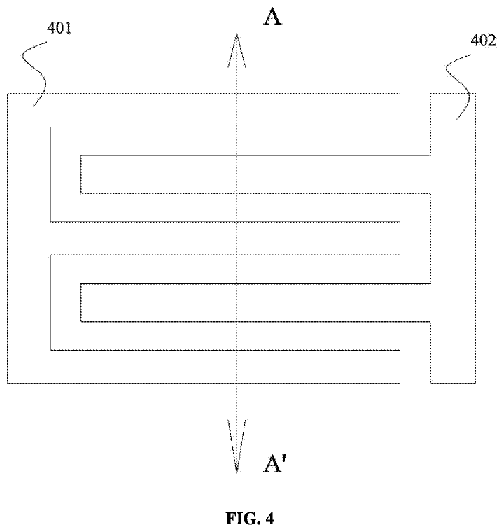

A2. The base structure is trenched: a curved division trench is formed by trenching the base structure from a top layer to a bottom layer, thus the base structure is divided into two staggered and mutually separated interdigitated structures 401 and 402 by the division trench, referring to FIG. 4 and FIG. 5.

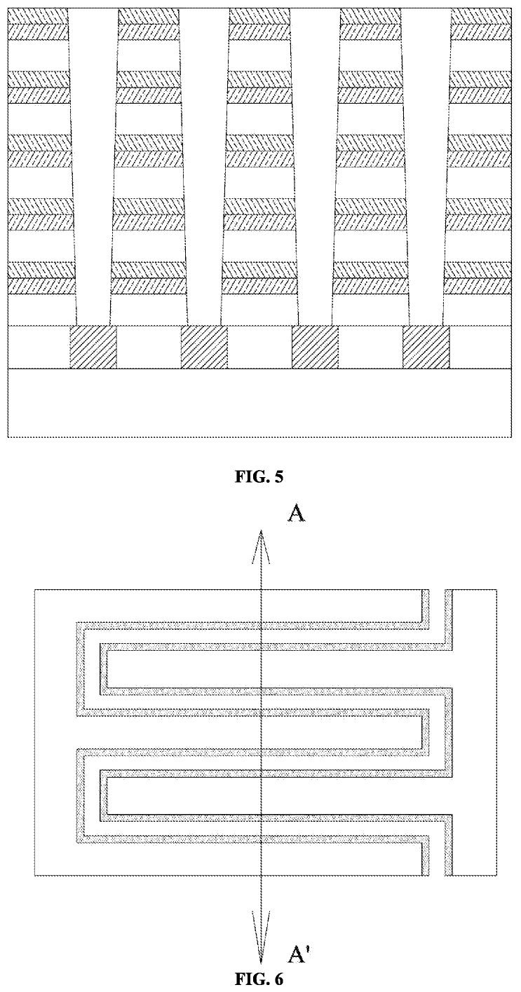

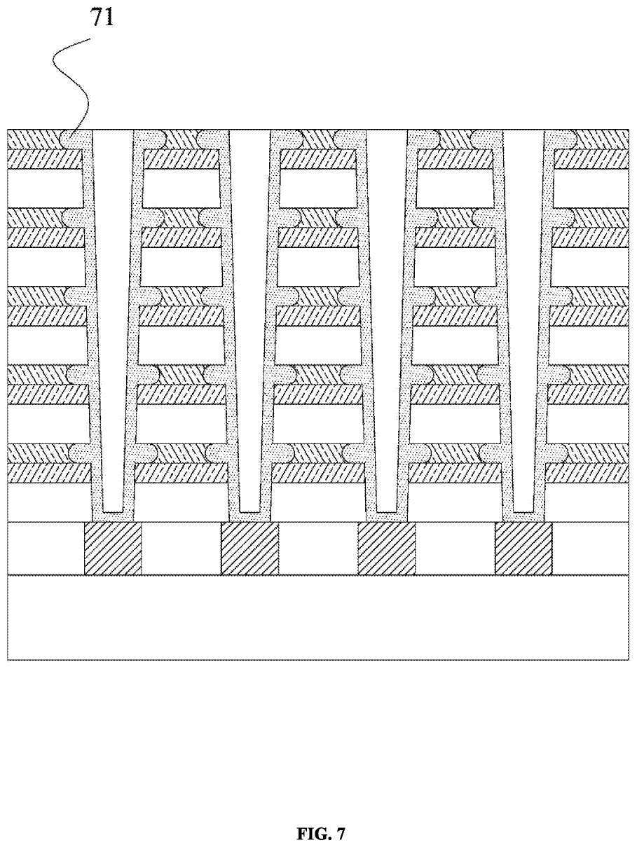

A3. On the inner wall of the division trench, the low-resistance silicide (metal silicide) layer is selectively etched to form a recess, and then an insulating material is isotropically deposited on the inner wall of the division trench to fill the trench formed in step A, thus forming an insulating region 71, referring to FIG. 6 and FIG. 7. The minimum depth of the recess may be determined by the characteristics of a programmable medium. By taking an anti-fuse OTP (one-time programmable) memory as an example, the minimum depth of the recess is determined to prevent the breakdown of the programmable medium. For example, if the thickness of the programmable medium is 5 nm, then, the minimum depth of the recess may be 1 to 1.5 times of that of the programmable medium, i.e., 5 nm to 7.5 nm. The maximum depth of the recess is determined by the minimum width of the vertical electrode, the required resistance, and the time cost for processing. For example, if the width of the vertical electrode is 0.28 um, and more than 10% of conductive resistance needs to be reduced, then the maximum depth of the recess etched on the side wall may be 5% to 10% of the width of the electrode, i.e., 13 nm to 27 nm.

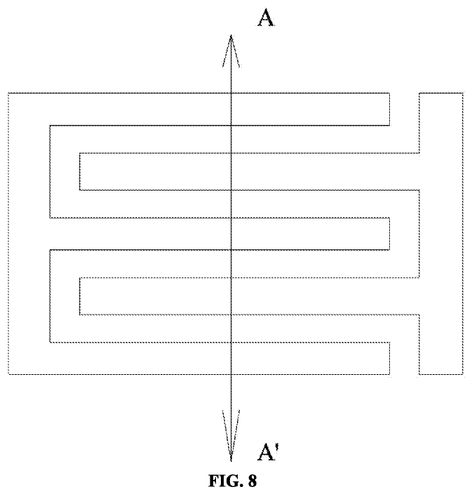

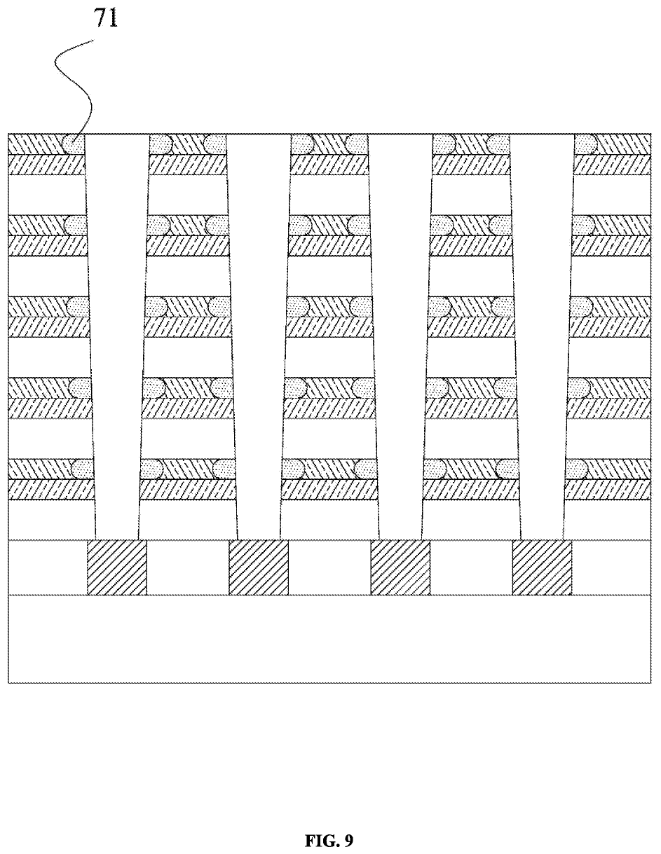

A4. Excessive insulating medium on the inner wall of the division trench is removed in a vertical etching manner to expose the base structure, referring to FIG. 8 and FIG. 9.

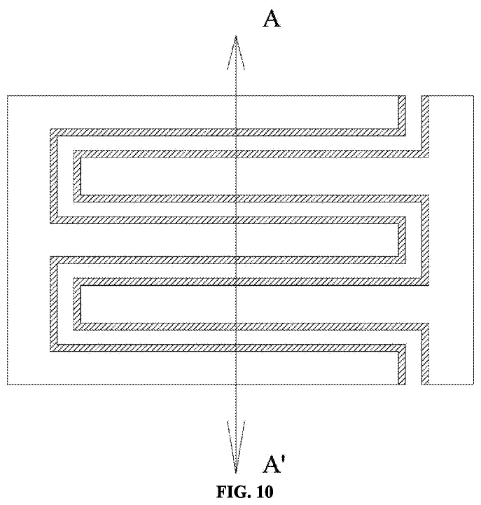

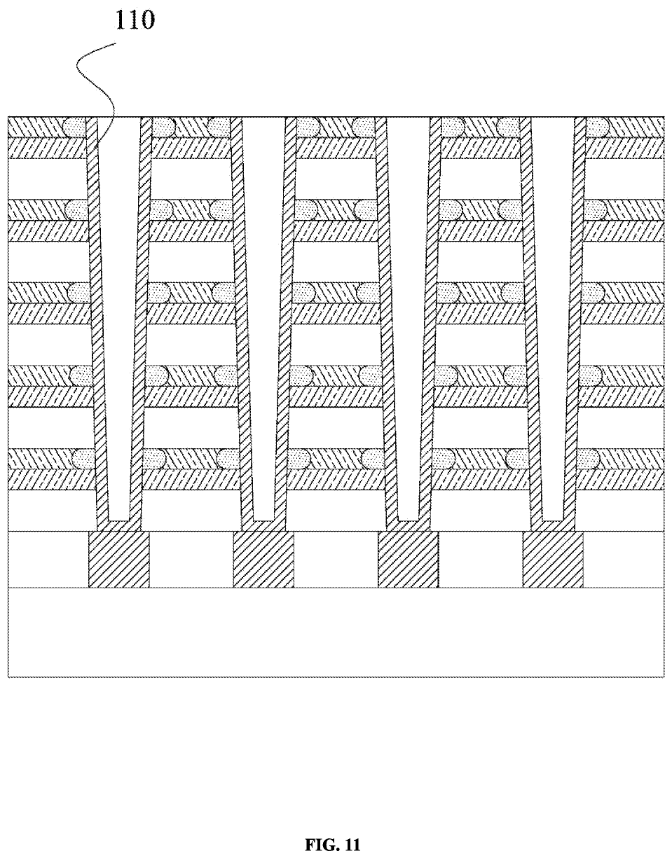

A5. An insulating material is deposited on the inner wall of the division trench as the storage medium, thus forming a storage medium layer 110 for covering the inner wall of the division trench, referring to FIG. 10 and FIG. 11.

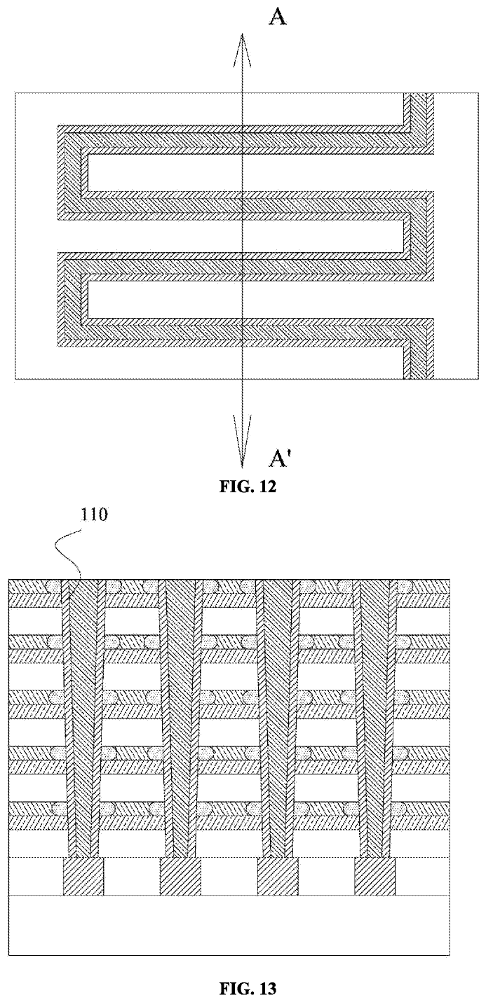

A6. The division trench is filled with an insulating medium, referring to FIG. 12 and FIG. 13.

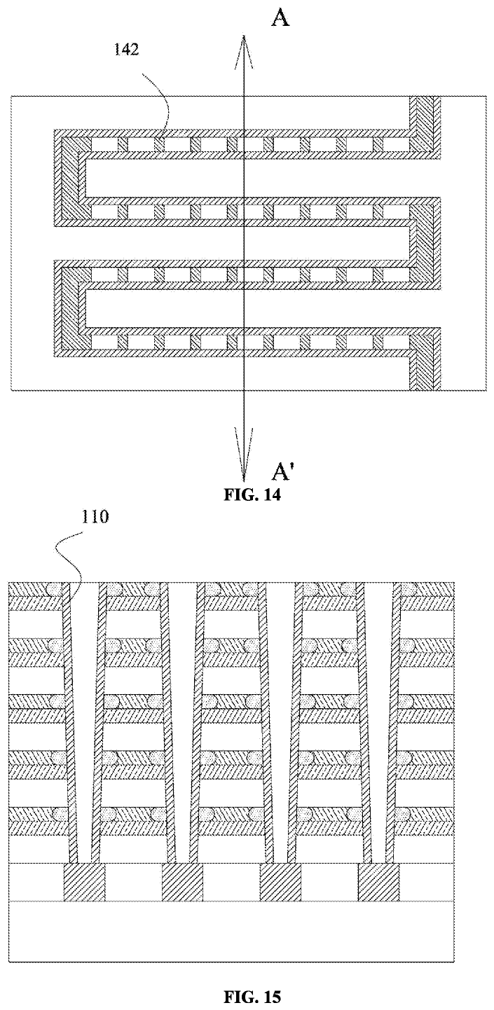

A7. Memory cell holes are etched along the division trench filled with the insulating medium by using an under-mask etching process to expose the base structure from the etched memory cell holes. In the present disclosure, the insulating medium 142 between two adjacent memory cell holes may employ a small thickness, or, a spacing distance between the two adjacent memory cell holes may be made relatively small depending on current mature etching techniques (e.g., 10 nm and below), and remains not less than the breakdown thickness of the insulating medium (e.g., the breakdown thickness of a silicon dioxide layer is 0.5 nm to 5 nm), referring to FIG. 14 and FIG. 15.

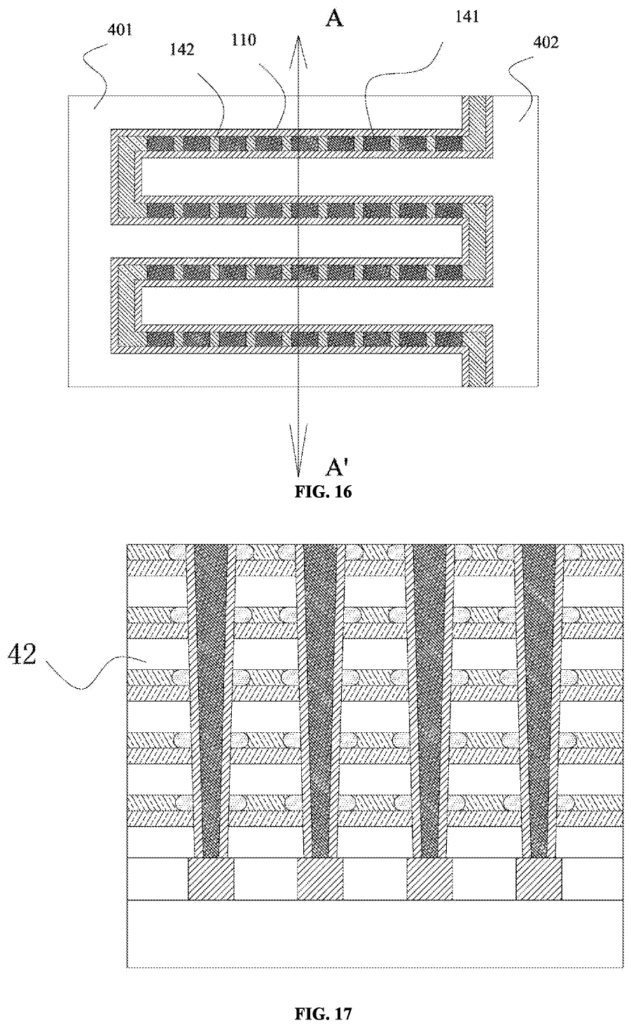

A8. Vertical electrodes 141 are disposed in the memory cell holes, referring to FIG. 16 and FIG. 17.

The vertical electrodes should be electrically connected to the underlying circuit, via bottom regions penetrating through the memory holes by etching process before the vertical electrodes being disposed, or the bottom regions of the memory holes being broken down by high voltage after the vertical electrodes are disposed.

### Embodiment 2 (with Buffer Layer)

Referring to FIG. 18, the difference between this embodiment and embodiment 1 is that a buffer layer 180 is further disposed on the surface of the storage medium layer, and the formed memory is of a four-layer structure of “vertical electrode/buffer layer/storage medium layer/low-resistance semiconductor layer”.

In the manufacturing process, step A5 in embodiment 1 is replaced with the following step B5:

B5: The insulating material is deposited on the inner wall of the division trench as a storage medium, thus forming a storage medium layer 110 for covering the inner wall of the division trench; and then the buffer layer 180 is deposited on the surface of the storage medium.

The subsequent steps are the same as above.

### Embodiment 3

This embodiment comprises the following steps:

C1. A base structure is formed on an underlying circuit 43: a preset number of first conductive medium layers and insulating medium layers are provided in a manner that the first conductive medium layers 41 and the insulating medium layers 42 are alternately stacked on each other so as to form the base structure. The first conductive medium layers 41 each comprise a low-resistance semiconductor layer 411 and a low-resistance silicide layer 410, one stacking on top of the other, referring to FIG. 2 and FIG. 3.

C2. The base structure is trenched: a through curved division trench from a top layer to a bottom layer is formed in the base structure, thus the base structure is divided into two staggered and mutually separated interdigitated structures 401 and 402 by the division trench, referring to FIG. 4 and FIG. 5.

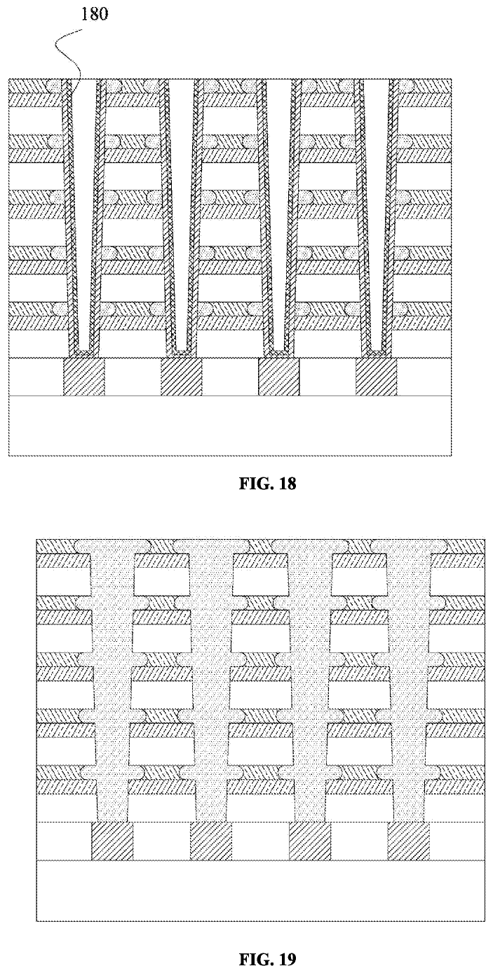

C3. On the inner wall of the division trench, a metal silicide layer is selectively etched to form a recess, and then an insulating material is filled in the division trench, including the recess formed in step A, referring to FIG. 19.

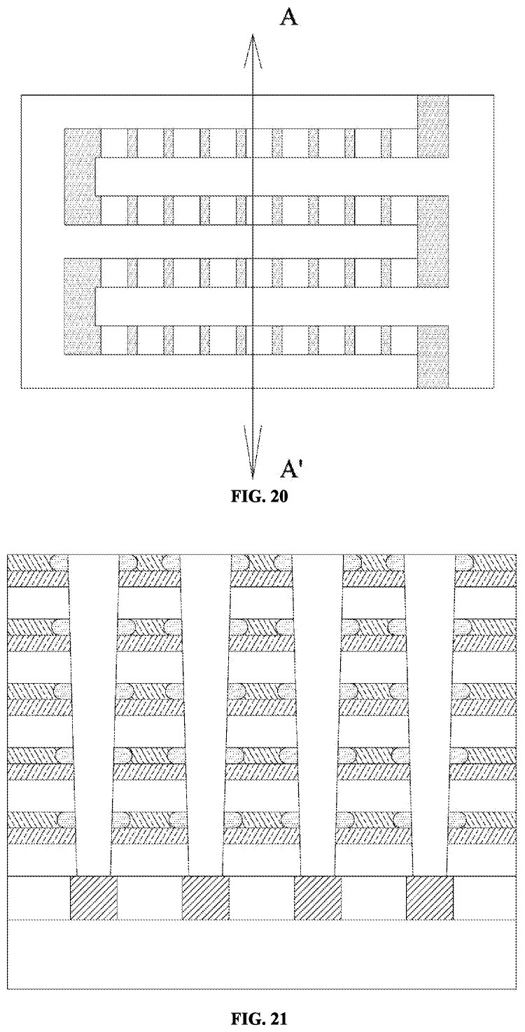

C4. Memory cell holes are etched along the division trench filled with an insulating medium by using an under-mask etching process, and the base structure is exposed inside the etched memory cell holes, referring to FIG. 20 and FIG. 21.

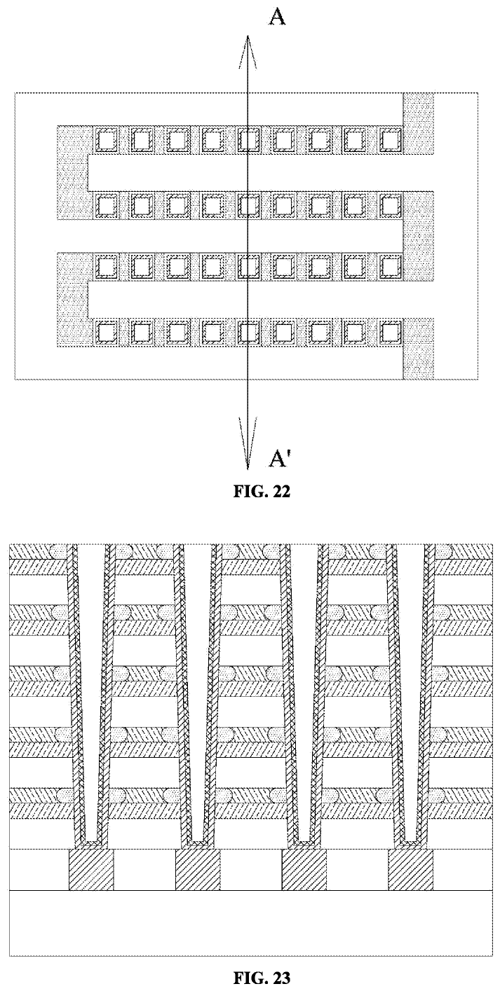

C5. The insulating material is deposited on the current inner wall of each memory cell hole as a storage medium, thus forming a storage medium layer 110 for covering the inner wall of the division trench; and then a buffer layer is deposited on the surface of the storage medium layer, referring to FIG. 22 and FIG. 23.

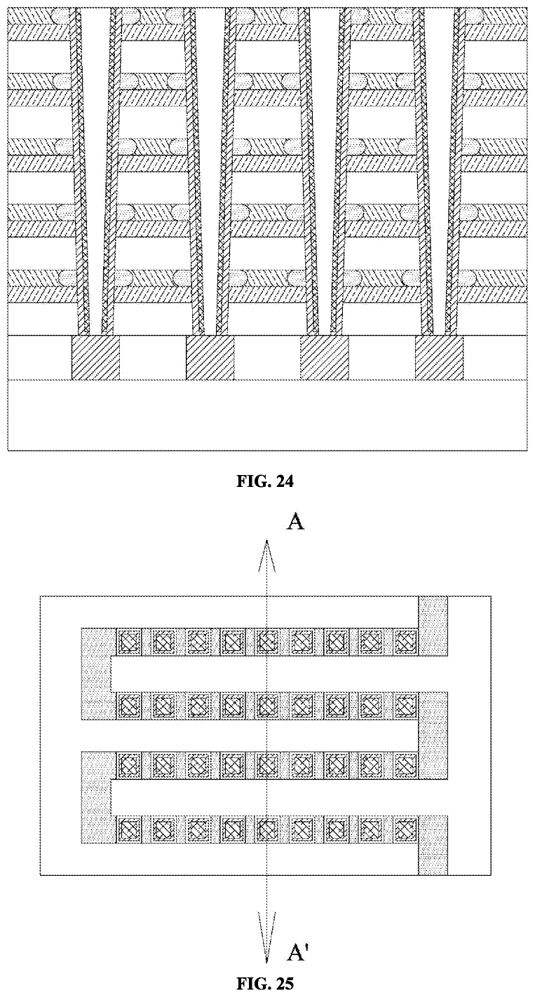

C6. A deep hole is etched to expose the underlying circuit, referring to FIG. 24.

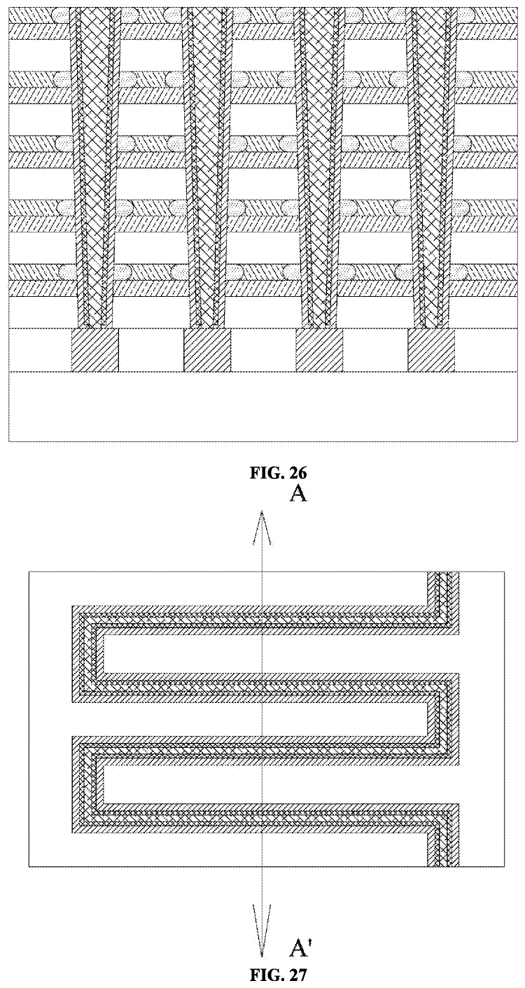

C7. Vertical electrodes 141 are disposed in the memory cell holes, referring to FIG. 25 and FIG. 26.

### Embodiment 4

D1. A base structure is formed on an underlying circuit 43: a preset number of first conductive medium layers and insulating medium layers are provided in a manner that the first conductive medium layers 41 and the insulating medium layers 42 are alternately stacked on each other so as to form the base structure. The first conductive medium layers 41 each comprise a low-resistance semiconductor layer 411 and a low-resistance silicide layer 410, one stacking on top of the other, referring to FIG. 2 and FIG. 3.

D2. The base structure is trenched: a through curved division trench from a top layer to a bottom layer is formed in the base structure, thus the base structure is divided into two staggered and mutually separated interdigitated structures 401 and 402 by the division trench, referring to FIG. 4 and FIG. 5.

D3. On the inner wall of the division trench, the metal silicide layer is selectively etched to form a recess, and then an insulating material is isotropically deposited on the inner wall of the division trench to fill the recess formed in step A, thus forming an insulating region 71, referring to FIG. 6 and FIG. 7.

D4. Excessive insulating medium on the inner wall of the division trench is removed in a vertical etching manner to expose the base structure, referring to FIG. 8 and FIG. 9.

D5. The insulating material is deposited on the inner wall of the division trench as the storage medium, thus forming a storage medium layer 110 for covering the inner wall of the division trench, referring to FIG. 10 and FIG. 11.

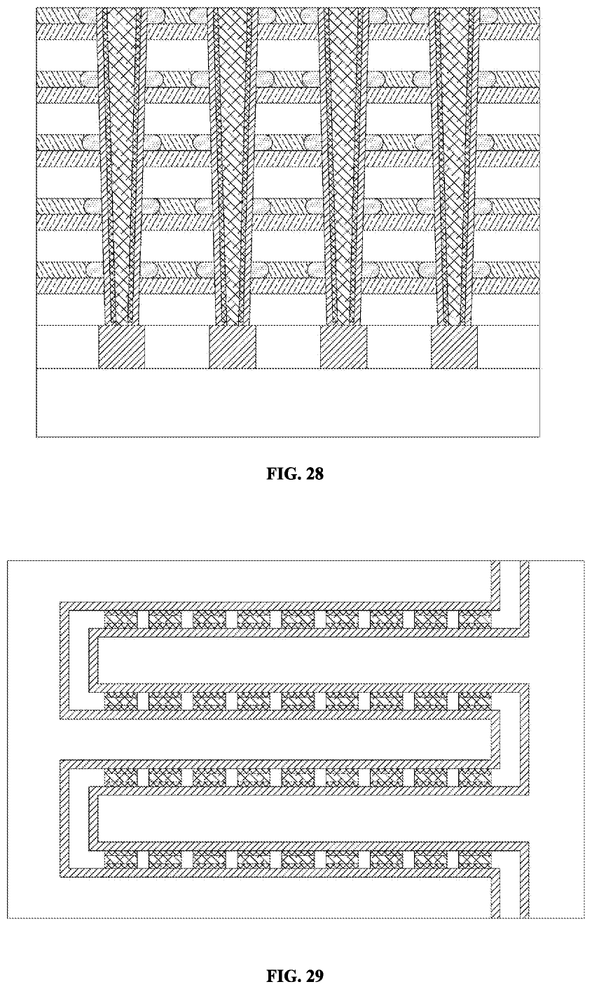

D6. A buffer material is deposited on the inner wall of the division trench to form a buffer layer, then a deep hole is etched to expose the underlying circuit, and the division trench is filled with a low-resistance semiconductor as an electrode material, referring to FIG. 27 and FIG. 28.

D7. Isolation trenches are etched along the division trench filled with the electrode material by using an under-mask etching process, thus forming vertical electrodes, referring to FIG. 29.

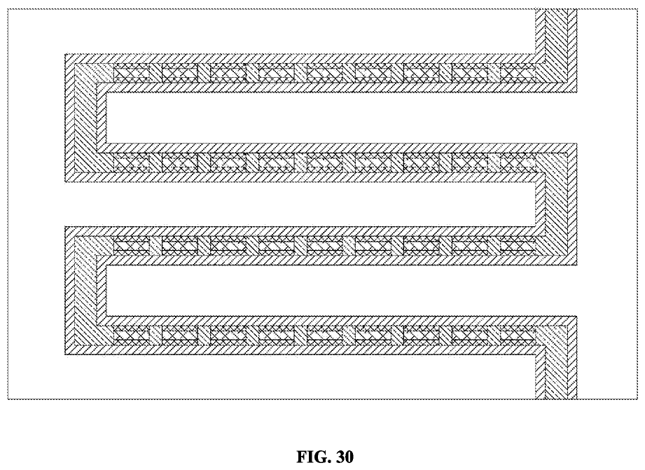

D8. The insulating material is disposed in the isolation trenches to form isolation pillars, referring to FIG. 30.

What is claimed is:

1. A three-dimensional multilayer memory with interconnection of low-resistance silicides, comprising an underlying circuit part and a base structure disposed on the underlying circuit part, wherein the base structure is divided into two interdigitated structures which are independent of each other by a curved division trench, referred to as a first interdigitated structure and a second interdigitated structure, respectively: the base structure comprises first conductive medium layers and insulating medium layers which are alternately stacked on each other from bottom to top: at least three memory cell holes are disposed side by side in the curved division trench, a vertical electrode is disposed in each memory cell hole, and an insulating isolation pillar is disposed between two adjacent memory cell holes:
the first conductive medium layers each comprise a low-resistance semiconductor, the vertical electrodes and the low-resistance semiconductors of the interdigitated structures as well as a storage medium therebetween form a memory structure;
the memory is a PN junction type semiconductor memory, a Schottky semiconductor memory, a resistance change memory, a magnetic phase change memory, a phase change memory or a ferroelectric memory, and the storage medium is an insulating medium;
wherein the first conductive medium layers each comprise a low-resistance semiconductor layer and a low-resistance silicide layer, one stacking on top of the other;
an insulating region is disposed in the low-resistance silicide layer, close to the storage medium, and the insulating region is configured to isolate the low-resistance silicide in the low-resistance silicide layer from the storage medium.

2. The three-dimensional multilayer memory with interconnection of low-resistance silicides according to claim 1, wherein a buffer layer is disposed between the vertical electrode and the storage medium.

3. The three-dimensional multilayer memory with interconnection of low-resistance silicides according to claim 1, wherein
the low-resistance silicide is metal silicide; and
the low-resistance semiconductor layer is heavily-doped polycrystalline silicon.

4. A manufacturing method for a three-dimensional multilayer memory with interconnection of low-resistance silicides, comprising the following steps:
1) forming a base structure: providing a preset number of first conductive medium layers and insulating medium layers in a manner that the first conductive medium layers and the insulating medium layers are alternately stacked on each other to form the base structure;
2) trenching the base structure: forming a curved division trench by trenching the base structure from a top layer to a bottom layer, thus dividing the base structure into two staggered and mutually separated interdigitated structures by the division trench;
3) forming a preset number of memory cell holes in the division trench, providing an insulating medium between the adjacent memory cell holes, disposing a vertical electrode in each memory cell hole, and providing a storage medium layer between the vertical electrode and the interdigitated structure, wherein the vertical electrode, the storage medium and the first conductive medium are all made of materials conforming to the materials required by the preset memory, and the memory is a PN junction type semiconductor memory, a Schottky semiconductor memory, a resistance change memory, a magnetic phase change memory, a phase change memory, or a ferroelectric memory;
wherein in step 1), the first conductive medium layers each comprise a low-resistance semiconductor layer and a low-resistance silicide layer, one stacking on top of the other;
after step 2) and before step 3), the method further comprises the following steps:
A) etching a metal silicide layer on an inner wall of the division trench to form a recess; and
B) filling the recess formed in step A with an insulating material.

5. The manufacturing method for the three-dimensional multilayer memory with interconnection of low-resistance silicides according to claim 4, wherein in step 3), the memory cell hole is a through hole penetrating through the base structure.

6. The manufacturing method for the three-dimensional multilayer memory with interconnection of low-resistance silicides according to claim 4, wherein step B) comprises the following step: filling the division trench as well as the recess formed in step A with the insulating material:
step 3) comprises the following steps:
3.1. vertically etching the filled insulating medium until the inner wall of the division trench is exposed, thus forming the memory cell holes disposed side by side along the division trench, wherein an insulating material is provided between the adjacent memory cell holes;
3.2. depositing the insulating material on the inner wall of each memory cell hole as the storage medium;
3.3. depositing a buffer material on the inner wall of each memory cell hole;
3.4. removing the insulating material and the buffer material at a bottom region of each memory cell hole to expose the underlying circuit; and
3.5. filling each memory cell hole with a vertical electrode material.

7. The manufacturing method for the three-dimensional multilayer memory with interconnection of low-resistance silicides according to claim 4, wherein step B) comprises the following step: depositing an insulating material on the inner wall of the division trench to fill the recess formed in step A at the same time;
step 3) comprises the following steps:
3.1. removing the insulating material covered on the inner wall of the division trench, and retaining the insulating material filled in the recess;
3.2. depositing the insulating material on the inner wall of the division trench as the storage medium;
3.3. depositing a buffer material on the inner wall of the division trench;
3.4. removing the insulating material and the buffer material at the bottom region corresponding to the position of a circuit connection point in the division trench so as to expose the underlying circuit;
3.5. filling the division trench with a vertical electrode material;
3.6. vertically etching the vertical electrode material and the buffer material filled in the division trench so as to form various independent vertical electrodes separated by isolation holes; and
3.7. filling the isolation holes with the insulating material.
